(19) United States
(12) Patent Application Publication
(10) Pub. No.: US 2009/0058262 A1
(43) Pub. Date: Mar. 5, 2009

(54) Alkaline fluoride dope molecular films and applications for p-n junction and field-effect transistor

(76) Inventors: Zheng-Hong Lu, Toronto (CA); Yanyan Yuan, Toronto (CA)

Correspondence Address: Ralph A. Dowell of DOWELL & DOWELL P.C., 2111 Eisenhower Ave, Suite 406, Alexandria, VA, 22314, US

(21) Appl. No.: 11/666,551

(22) PCT Filed: Oct. 28, 2005
(86) PCT No.: PCT/CA05/01655

§ 371 Date: Nov. 7, 2008

Related U.S. Application Data
(60) Provisional application No. 60/622,619, filed on Oct. 28, 2004.

(51) Int. Cl. H01J 1/63; H01B 1/02

(52) U.S. Cl. 313/503; 252/521.5

(57) ABSTRACT

The present invention provides a molecular film by alkaline fluoride n-doping into an electron transport host. The present invention also provides a molecular film where the transport molecule can either be tris (8-hydroxyquinolinato) (Alq3) or fullerene. The present invention further provides a p-n junction and a field-effect transistor of the same materials. Furthermore, the present invention provides a molecular film by fullerene p-doping into a hole transport molecular host. The present invention further provides a P-I-N light-emitting device which includes a substrate and a first electrically conductive layer defining an anode electrode layer on the substrate. The device includes the p-doped molecular film as hole injection layer deposited on the anode, the n-doped electron transport film as electron injection layer, and a second electrically conductive layer defining a cathode electrode layer on the electron injection layer. The device includes a layer of light-emissive material between the p-doped layer and the n-doped layer.

### CROSS REFERENCE TO RELATED U.S. APPLICATIONS

This patent application relates to, and claims the priority benefit from U.S. Provisional Patent Application Ser. No. 60/622,619 filed Oct. 28, 2004 which is incorporated herein by reference in its entirety.

### FIELD OF THE INVENTION

The present invention relates to a method of n-type doping of molecular semiconductors using fluoride compounds, and a method of p-type doping of molecular semiconductors using fullerene. The present invention also relates to a P-I-N light-emitting structure, where P stands for p-type hole transport molecule layer(s), I stands for light emissive layer(s), and N stands for n-type electron transport layer(s).

### BACKGROUND OF THE INVENTION

A typical organic light-emitting device includes an anode, an active light-emitting zone comprising one or more electroluminescent organic material(s), and a cathode. One of the electrodes is optically transmissive while the other one may be optically reflective. The function of the anode is to inject positively charged holes into the light-emitting zone, and that of the cathode is to inject electrons into the emission zone. The process of recombination of the electrons and the holes leads to the creation of light which is emitted through the optically transmissive electrode, or through both if the other electrode is also transparent at the optical wavelengths emitted by the device.

U.S. Pat. No. 4,356,429 discloses inserting a hole-transport organic layer between the anode and the light emission zone, and an electron-transport organic layer between the cathode and the emission zone.

Since neutral molecules contain no “intrinsic” charge, i.e. extra charge, in the molecules, charges have to be injected from the electrodes during device operation. In order to improve the device operation stability and performance, it is highly desirable to provide an n-doped electron layer and a p-doped hole transport layer. In an n-doped molecular semiconductor, the dopant will donate electron charges to the host molecule and in a p-doped molecular semiconductor, the dopant will accept electron charges from the host molecule.

U.S. Pat. No. 4,204,216 discloses the use of metals with Pauling electronegativity value less than 1.6 as n-type dopants for organic polymeric semiconductors.

U.S. Pat. No. 4,222,903 discloses the use of bromine, iodine, iodine chloride, iodine bromide, and arsenic pentafluoride as p-type dopants.

United State Patent Publication No. US20030230980 discloses a phosphorescent OLED using a P-I-N structure. This patent publication discloses the use of Li metal as an n-type dopant and F4-TCNQ (tetrafluoro-tetracynao-quinodimethane) molecules as p-type dopants.

As a family member of naturally occurring allotropes of carbon, fullerene materials are known for their robust structures and superior charge transport properties. U.S. Pat. No. 5,861,219 discloses the use of fullerenes as a dopant added to a host metal complex of 5-hydroxy-quinoxaline used in organic light emitting diodes. The host metal complex of 5-hydroxy-quinoxaline is contained in the electroluminescent layer which forms the emission zone in the structure. United States Patent Publication US 2002/0093006 A1 discloses the use of a fullerene layer as the light emissive layer in an organic light emitting diode structure.

Japan Patent 3227784 and Japanese patent application Serial No. 04-144479 disclose the use of fullerenes as a hole transport layer.

U.S. Pat. No. 5,171,373 discloses the use of fullerenes in solar cells. U.S. Pat. No. 5,759,725 discloses the use of fullerenes in photoconductors.

The use of fullerenes as an interface layer between the hole transport layer and the light emission layer has been disclosed by Keizo Kato, Keisuke Suzuki, Kazunari Shinbo, Futao Kaneko, Nozomu Tsuboi, Satosh Kobayashi, Toyoyasu Tadokoro, and Shinichi Ohta, Jpn. J. Appl. Phys. Vol. 42, 2526 (2003).

U.S. Pat. No. 5,776,622 issued to Hung et al. discloses an electroluminescence device including an anode, cathode and EL layer, in which the cathode layer contacts the EL layer and includes a fluoride layer in direct contact with the EL layer and a conductive layer in direct contact with the fluoride layer.

It would be very advantageous to provide a method of providing n-type doped molecular semiconductor by using chemically stable dopant materials such as LiF. It will also be advantageous to provide a method to provide a p-type molecular semiconductor by using stable electron acceptor such as fullerene to improve the thermal stability and the adhesion to a substrate.

### SUMMARY OF THE INVENTION

The present invention provides n-doped electron-transport molecular semiconductors doped using by anions from ionic compounds as n-type dopant. In this aspect of invention, electron transport molecules gain extra charge from the anion.

The present invention provides p-doped electron-transport molecular semiconductors doped using fullerenes as dopants wherein charge transfer between the molecules which transport holes and the dopant fullerene produce p-type doping to the molecules which transport holes.

In one aspect of the invention there is provided a molecular film comprising an electron transport material including molecules which transport electrons and an alkali fluoride as a dopant, wherein charge transfer between the molecules which transport electrons and the dopant produces n-type doping to the molecules which transport electrons.

The electron transport molecule may be tris (8-hydroxyquinolinato) (Alq3) or it may be a fullerene C60, C70 or mixtures of C60 and C70.

The alkali fluoride may be LiF, MgF₂, CaF₂, SrF₂ and BaF₂, but preferably is LiF.

The present invention also, provides a molecular film comprising a hole transport material comprising molecules which transport holes and a fullerene as a dopant, wherein charge transfer between the molecules which transport holes and the dopant fullerene produce p-type doping to the molecules which transport holes.

The molecules which transport holes may be NPB (N,N′-bis(I-naphthyl)-N,N′-diphenyl-1,1′-biphenyl-4,4′-diamine) or TPD (N,N′-diphenyl-N,N′-bis(3-methylphenyl)-1,1′-biphenyl-4,4′-diamine). The fullerene may be C60, C70 or mixtures of C60 and C70.

The present invention also provides a light-emitting device, comprising:

a) a substrate;

b) a first electrically conductive layer defining an anode electrode layer on the substrate;

c) a p-type doped hole injection layer on the anode electrode layer:

d) a hole transport layer on the p-type doped hole injection layer;

e) a layer of a light emissive material located on said hole transport layer;

f) an electron transport layer on the layer of light emissive material;

g) an n-type doped electron injection layer located on said electron transport layer; and

h) a second electrically conductive layer defining a cathode electrode layer on said n-type doped electron injection layer, wherein either said first electrically conductive layer and the substrate is at least partially transparent or the a second electrically conductive layer is transparent to light produced in said light emissive material.

### BRIEF DESCRIPTION OF THE DRAWINGS

The layered structure and the light-emitting device produced according to the present invention will now be described, by way of example only, reference being made to the accompanying drawings, in which:

FIG. 1 shows X-ray photoelectron spectroscopic (XPS) F1s spectra results for (a) pristine LiF, (b) Alq3-LiF, (c) C₆₀—LiF, and (d) TPD-LIF;

FIG. 2 shows optical absorption spectra of various LiF-doped and pristine molecular semiconductors for (a) pristine Alq3 (solid line) and Aq3-LiF (dashed line), (b) pristine C60 (solid line) and C60-LiF (dashed line), (c) pristine NPB (solid line) and NPB-LiF (dashed line), and (d) pristine TPD (solid line) and TPD-LiF (dashed line);

FIG. 3a shows an optical micrograph of a pure TPD hole-transport organic film as deposited;

FIG. 3b shows an optical micrograph of a TPD hole-transport organic film as deposited and after being annealing;

FIG. 3c shows an optical micrograph of a C60 doped TPD hole-transport organic film as deposited;

FIG. 3d shows an optical micrograph of a C60 doped TPD hole-transport organic film as deposited and after thermal treatment;

FIG. 4 is a sectional view of a layered P-I-N structure constructed in accordance with the present invention;

FIG. 5 shows plots of current density versus voltage (V) of P-I-N OLEDs which include a 10 nm thick p-doped hole injection layer made of NPB doped with 0% (reference), 3 wt %, 30 wt %, and 50 wt % nano-bucky-ball (NBB) or fullerene C60 respectively and with an emission ‘I’ layer which is 40 nm thick Alq, and an n-doped electron injection layer which is the Alq delta doped with 1.5 nm thick LiF;

FIG. 6 shows plots of luminance versus voltage of P-I-N OLEDs of FIG. 5;

FIG. 7 shows plots of current efficiency as a function of operating voltage of the P-I-N OLEDs of FIG. 5;

FIG. 8 shows plots of current versus voltage of the P-I-N OLEDs constructed according to the present invention. Here the hole injection layer is 5 wt. % C60-doped NPB with a thickness varied from 0 nm, 10 nm, to 50 nm. The hole transport layer is NPB with a thickness varied from 60 nm to 10 nm. The total sum thickness of hole injection layer and hole transport layer thickness is kept at a constant value of 60 nm. The emission “I” layer is 40 nm thick Alq. The n-doped electron injection layer is the Alq delta doped with 1.5 nm thick LiF.

FIG. 9 shows plots of luminance versus voltage of P-I-N OLEDs of FIG. 8; and

FIG. 10 shows plots of current efficiency versus voltage of P-I-N OLEDs of FIG. 8.

### DETAILED DESCRIPTION OF THE INVENTION

### Definitions

As used herein, the phrase “electron injection layer” means a thin-film material having a primary function of injecting or transporting electrons across the layer from one region to another region.

As used herein, the phrase “hole injection layer” means a thin-film material having a primary function to inject or transport holes across the layer from one region to another region.

As used herein, the phrase “light emissive layer or light-emission layer” means a thin-film material having the primary function of emitting light.

As used herein, the phrase “electroluminescence layer” means a thin-film material having a primary function of emitting light under electrical stimulation.

As used herein, the term “fullerene” means nanostructured carbon consisting of 60, 70, or more carbon atoms self-bonded in spherical forms which are also referred to as Buckminster fullerenes, nano bucky balls (NBB) or bucky balls (BB) in the literature. The carbon atoms may be bonded to additional atoms or functional groups.

The present invention provides a method of doping molecular semiconductors used in electron-transport materials with n-type dopants using anions from ionic compounds so that the molecular semiconductors gain extra charge from the anions. An example is using an anion such as F⁻ of from an ionic compound such as LiF. The present invention also provides a method of fabricating an n-type doped electron transport layer for organic electroluminescent device application.

The present invention also provides a method of doping molecular semiconductors used in hole-transport layers with p-type dopants, an example being using a fullerene as p-type-dopant. Fullerenes are strong electron acceptors so that they are able to gain charge from hole-transporting molecules.

The present invention also provides a thermally stable fullerene-doped molecular layer on an inorganic surface for application in an organic electroluminescent device.

The present invention also provides an organic molecule based electroluminescence device using an n-doped molecular semiconductor as the electron transport layer, a p-doped molecular semiconductor as the hole injection layer, and an electroluminescent layer.

### EXAMPLE 1

### LiF-Doped Electron Transport Molecules with N-Type Characteristics

The doping of organic compounds with LiF was carried out by co-evaporation method. Double-side polished sapphire wafers were used as substrates. The deposition pressure in the chamber was ˜10⁸ torr. The weight ratio of LiF versus organic molecules was controlled at 1:10, a ratio optimized for OLED performance. Pure LiF, TPD (N,N′-diphenyl-N,N′-bis(3-methylphenyl)-1,1′-biphenyl-4,4′-diamine), NPB (N,N′-bis(I-naphthyl)-N,N′-diphenyl-1,1′-biphenyl-4,4′-diamine), C₆₀ and Alq3 (tris (8-hydroxyquinolinato) aluminum), films were also prepared as reference samples. The thickness of all samples was 1000 Å.

The films were characterized by X-ray photoemission spectroscopy and optical absorption spectroscopy. The XPS measurements were performed using a PHI 5500 ESCA system (base pressure ˜10⁻⁹ Torr) using Mg Kα radiation (1253.6 eV). Optical absorption spectra were recorded from 1500 nm to 700 nm using a Cary 500 UV-Vis-NIR spectrophotometer.

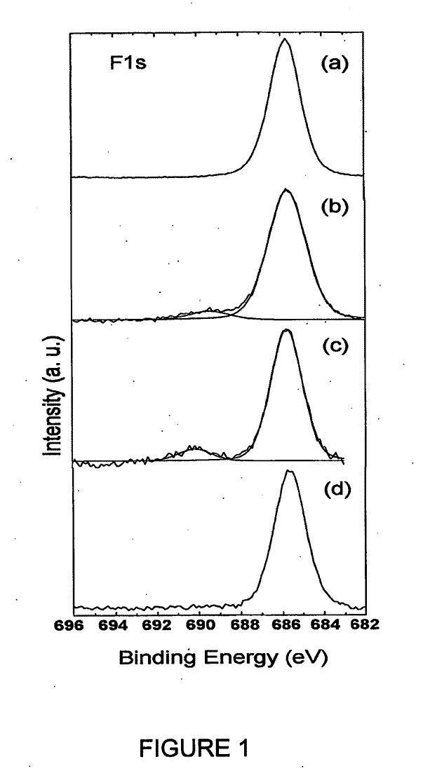

FIG. 1 shows the XPS F1s spectra for (a) pristine LiF, (b) Alq3-LIF, (c) C₆₀—LiF, and (d) TPD-LiF. As compared with spectrum recorded from pure LiF, the F1s spectrum from Alq3-LiF sample has two components which suggest two chemical states of F, one being LiF and another new state being LiF-Alq. Based on its chemical shift to a higher binding energy, it is concluded that this new F⁻(-Alq) species has lost valence charge to Alq, whose electron negativity is higher than that of Li⁺. It is well known that with a decrease in valence charge density, the repulsive electron-electron interaction between core shell and valence shell will decrease, and therefore the binding energy of the core level electrons to the nucleus will increase. Such a charge-transfer state peak was also observed in, C₆₀—LiF composites. On the contrary, for the two hole transport materials TPD and NPB (not shown), F1s spectra are the same as pristine LiF sample. There is no indication of the existence of any charge transfer states.

These results can be explained from chemical reaction properties of these organic molecules. Since electron transport materials (ETM) such as Alq3 are Lewis acids with high electron affinity, they tend to draw electrons from surrounding molecules. On the contrary, hole transport materials (HTM) are Lewis bases which readily donate electrons. Since the F⁻ anion is in a saturated state, it no longer has a high electronegativity as does a free F atom and consequently F⁻ anion has no further ability to accept charge from Lewis bases. Another classic example is HF molecule where, as the conjugate base, F⁻ is known to be a fairly strong base in terms of chemical reactivity. Therefore, the saturated F⁻ anion can donate charge to a more electronegative Lewis acid such as Alq3 and C₆₀.

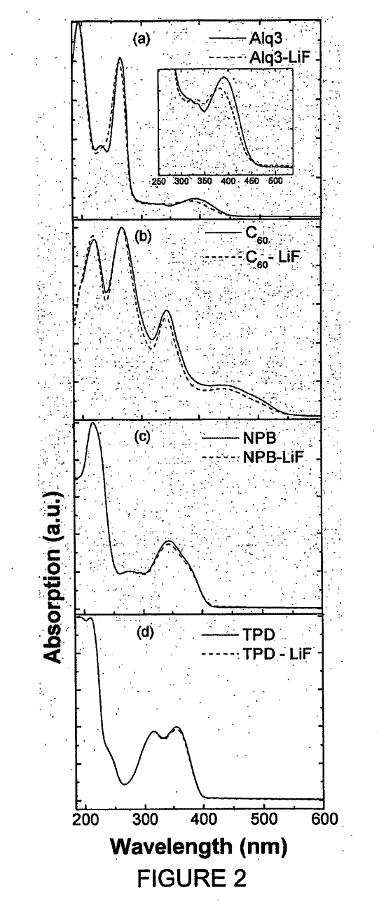

FIG. 2a shows the absorption spectra of Alq3 film with and without LiF doping. For Alq3 films, the electronic process of optical absorption is confined within a single molecule, with little contributions from intermolecular interactions. The optical absorption spectrum has two pronounced bands, one centered around 265 nm and another around 391 nm, and is consistent with published results (P. E. Burrows, Z. Shen, V. Bulovic, D. M. McCarty, S. R. Forrest, J. A. Cronin, and M. E. Thompson, J. Appl. Phys. 79, 7991 (1996). For LiF-doped sample, these absorption peaks shifted to shorter wavelengths. This blue shift is related to charge transfer between Alq3 and LiF, as observed from XPS.

The origin of this blue shift can be understood from molecular orbital calculations. Since the lowest unoccupied molecular orbitals (LUMOs) of Alq3 are localized on the pyridyl ring of one quinolate ligand, charge transfer occurs from F⁻ to the pyridyl ring (S. A. Van Slyke, P. S. Bryan, and F. V. Lovecchio, U.S. Pat. No. 5,150,006.). Thus, we can consider a partial chemical bond formed between electron donating F⁻ anion and pyridyl ring.

According to a molecular orbital calculation using Zemer Intermediate Neglect of Differential Overlap (ZINDO) method, an electron-donating substituent at the pyridyl side of the quinolate ligand will increase the energy of the vacant orbitals, resulting in a blue shift of the absorption spectrum of Alq3. This calculation also predicts a small amount of blue shift. For example, the shift is 10 nm for the absorption peak at 391 nm and 3 nm for the 265 nm peak respectively. In addition, the intensity of the first absorption peak at 391 nm decreased while the intensity of the small but sharp absorption peak at 334 nm increased. A similar trend of the changes of the peak intensity have been reported for the absorption spectra of Alq3 anion in solution and thin films (V. Kishore, A. Aziz, K. L. Narasimhan, N. Periasamy, P. S. Meenakshi, and S. Wategaonkar, Synth. Met. 126,199 (2002). V. V. N. Ravi Kishore, N. Periasamy, B. Bhattacharjee, R. Das, P. L. Paulose, and K. L. Narasimhan, Chem. Phys. Lett. 367, 657 (2003)). which further supports our conclusion about the direction of charge transfer.

FIG. 2b shows the absorption of C₆₀—LiF composites films. As compared with pure C₆₀, no obvious band shift was observed from the doped sample. This suggests that the electronic structure of C₆₀ remained unaffected after accepting charge from LiF. This might be due to the large close shell conjugated system of C₆₀, which is difficult to be disturbed. The absorption spectra of many C₆₀ based compound have been reported to be similar to that of pure C₆₀ (P. V. Dudin, S. V. Amarantov, V. G. Stankevitch, V. N. Bezmelnitsyn, A. V. Ryzkov, O. V. Boltalina, and M. B. Danailov, Surf. Rev. Lett. 9, 1339 (2002)).

FIGS. 2c and 2d show the absorption spectra of NPB and TPD films respectively with and without LiF doping. Since there is no reaction between LiF and these two molecules, the absorption spectra of the composites remain the same as those of pristine organic molecules. The experimental data shows that F⁻ anion acts as a n-type donor-donating electron charge to the electron transport molecules.

Therefore, the present invention provides a molecular film comprising an electron transport material including molecules which transport electrons and an alkali fluoride as dopant, wherein charge transfer between the molecules which transport electrons and the dopant produces n-type doping to the molecules which transport electrons.

The molecules of the electron transport material and the dopant may be selected on the basis that the energy of the highest occupied molecular orbital (HOMO) of the donor is selected to match the lowest unoccupied molecular orbital (LUMO) of the fullerene. The energy difference between the HOMO and LUMO is preferably less than 0.5 eV.

The electron transport molecule may be tris (8-hydroxyquinolinato) (Alq3) or a fullerene such as C60, C70 or mixtures of C60 and C70. The alkali fluoride may be LiF, MgF₂, CaF₂, SrF₂ and BaF₂, but is preferably LiF.

The n-doped molecular film may be applied as an electron transport layer on a hole transport layer to form a p-n junction. These p-n junction structures may be used to form semiconductor devices such as solar cells and other photo-voltaic devices such as sensors and detectors.

The n-doped molecular film may be applied as an interlayer between a metal electrode and a surface of a source junction in an n-type channel, and/or applied as an interlayer between a metal electrode and a drain junction of the n-type channel of a field-effect transistor.

### EXAMPLE 2

### Fullerene p-Doped Hole-Injection Film with Improved Thermal Stability

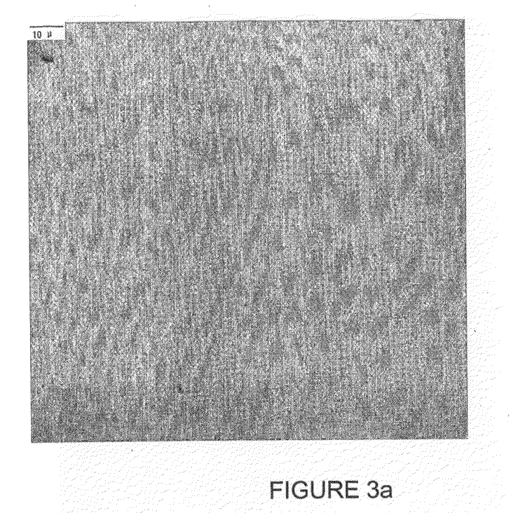

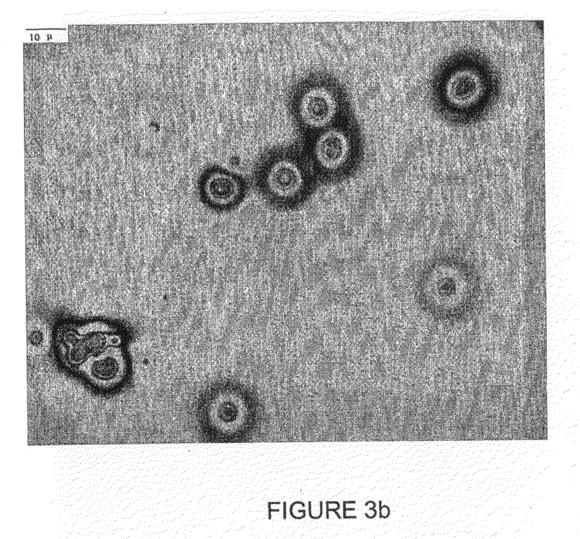

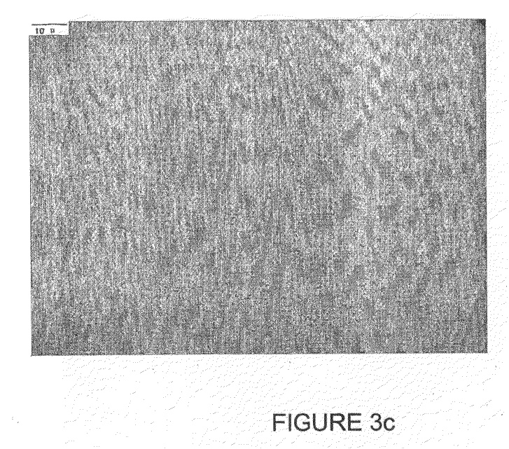

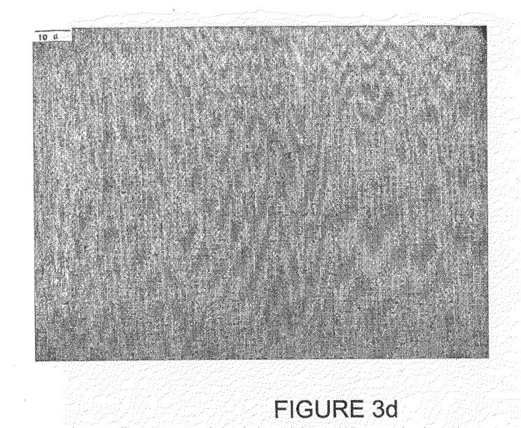

100 nm thick thin films of pure transport molecule TPD and C60 doped TPD specimen has been prepared by physical vapor phase deposition using technique as described in Example 1. The substrates are ITO coated glasses. In all cases the hole injection layer is in direct contact with the aforementioned substrate. Because of a large surface energy mismatch between inorganic ITO surface and organic surface, there is a rather poor adhesion at the interface between ITO and organic films. This poor adhesion leads to de-lamination at moderate temperature. FIG. 3a shows optical micrograph of pure TPD film as-deposited at room-temperature and FIG. 3b shows optical micrograph of pure TPD film after being annealed at 63° C. for one hour. The round spots shown in FIG. 3b indicate de-lamination at the ITO-TPD interface.

FIG. 3c shows optical micrograph of C60-doped TPD films as-deposited at room-temperature and FIG. 3d shows optical micrograph of the same doped sample after being annealed at 63° C. for one hour. FIG. 3d shows no de-lamination spots. The results clearly show that fullerene doped hole transport film has much improved thermal stability. This improved thermal stability is related to charge transfer activity between the fullerene dopant and host hole-transport molecules. Fullerene is known to be a strong electron acceptor whereas hole transport molecules are known to be strong electron donor. The charge transfer between fullerene and TPD create a strong permanent dipole thus providing a cross-linkage of the surrounding molecule. This linkage force creates a thermoset polymer-like system thus improve the thermal stability of the fullerene doped hole transport films. For example, Charles Goodyear discovered in 1844 that sulfur doped rubber promotes crosslinks between polymer chains which leads to much improved mechanical property. Moreover, the charge transfer will lead to electron deficiency in the hole transport molecule and consequently leads to p-type doping.

Therefore, the present invention provides a molecular film comprising a hole transport material which includes molecules which transport holes and a fullerene as a dopant, wherein charge transfer between the molecules which transport holes and the dopant produce p-type doping to the molecules which transport holes.

The molecules which transport holes may be NPB (N,N′-bis(1-naphthyl)-N,N′-diphenyl-1,1′-biphenyl-4,4′-diamine) or TPD (N,N′-diphenyl-N,N′-bis(3-methylphenyl)-1,1′-biphenyl-4,4′-diamine). The fullerene may be C60, C70 or mixture of C60 and C70.

This molecular film may be used as a primer coat on a surface for improved adhesion and thermal stability. It could also be applied as a hole transport layer on an electron transport layer to form a p-n junction. It may also be applied as a interlayer between a metal electrode and a surface of a source junction in an p-type channel, and/or applied as a interlayer between a metal electrode and a drain junction of said p-type channel of a field-effect transistor.

### EXAMPLE 3

### P-I-N Electroluminescent Device

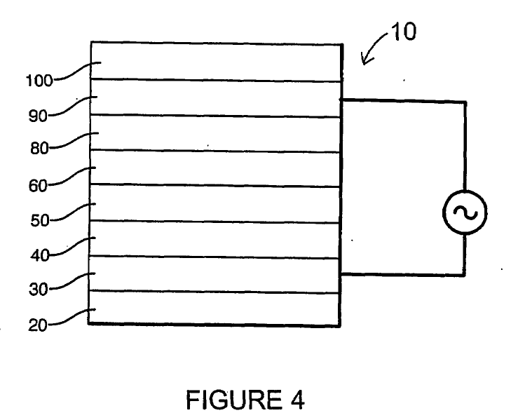

Referring to device 10 shown in FIG. 4, an EL device shown generally at 10 has been constructed to demonstrate the integration of n-doped electron injection layer (EIL) and a fullerene p-doped layer into a typical small organic molecule based device of the type disclosed in U.S. Pat. No. 4,356,429. The device 10 comprises a substrate 20, a conductive anode electrode layer 30, a p-doped hole injection layer (HIL) 40, a hole transport layer (HTL) 50 for hole transport, a light emissive or light-emission layer 60 formed on the hole transport layer 50 capable of emitting light, an electron transport layer (ETL) 70 formed on the light-emission layer 60, an n-doped electron injection layer (EIL) 80 formed on ETL 70, and an outer conductive cathode layer 90 formed on electron injection layer 80.

Substrate 20 may be a glass or alternatively it could be made of any material capable of providing mechanical support to thin films. It could be coated with functional thin-film transistors which may be used as electrical drivers. Substrate 20 may be optically transparent for light emitted from the light emissive layer 60. Alternatively, cathode layer 90 may be made of suitable materials and thickness to ensure light is coupled out of the light emissive layer 60 through this layer.

Conductive anode layer 30 is a hole Injection electrode when a positive bias is applied and it may be, for example, of ITO. Electrode layer 30 may also be any other metal or alloy with a high work function. For example, anode layer 30 may be selected from high work function conducting materials including SnO₂, Ni, Ag, Pt, Au, p++ semiconductors (c-Si, a-Si, a-Si:H, poly-silicon). Additional anode materials are disclosed in U.S. Pat. No. 4,885,211 which is incorporated herein in its entirety.

Hole injection layer 40 includes molecules which transport holes and a fullerene as dopant, wherein charge transfer between the molecules which transport holes and the dopant produce p-type doping to the molecules which transport holes. The molecules which transport holes may be NPB (N,N′-bis (I-naphthyl)-N,N′-diphenyl-1,1′-biphenyl-4,4′-diamine) or TPD (N,N′-diphenyl-N,N′-bis(3-methylphenyl)-1,1′-biphenyl-4,4′-diamine). The fullerene may be C60, C70 or mixture of C60 and C70.

Hole injection layer 40 is preferably an C60 doped NPB. The preferred C60 concentration ranges from 1 wt. % to 30 wt. %. The preferred thickness ranges from 5 nm to 50 nm.

Hole transport layer (HTL) 50 is preferably NPB and may have a thickness of about, but not limited to, 50 nm. It could also be any other one or more layers of organic or polymer materials capable of transporting holes and having a thickness range from about 10 nm to about 300 nm. The hole-transport layer 50 may be comprised of those materials disclosed in United States Patent Publication No. 20020180349 which is Ser. No. 10/117,812 published Dec. 5, 2002 which is incorporated herein by reference in its entirety, which application refers to U.S. Pat. Nos. 4,539,507; 5,151,629; 5,150,006; 5,141,671 and 5,846,666 which are all incorporated herein by reference in their entirety. This reference discloses different hole transport layer materials, electron transport layer materials, anode materials and cathode materials, which application refers to U.S. Pat. Nos. 4,539,507, 5,942,340 and 5,952,115 which are all incorporated herein by reference in their entirety.

Light emissive or light-emission layer 60 may be an organic electroluminescence layer comprised of, for example, tris-(8-hydroxyquinoline) aluminum (Alq) and may have a thickness of 25 nm. It could also be a layer of an organic compound capable of emitting different colors and having a thickness in the range from about 10 nm to about 100 nm. Other suitable materials useful for the light emission-layer include conjugated polymers such as poly (paraphenylene vinylene) (PPV); various members of PPV with and without pigment dyes such as disclosed in U.S. Pat. Nos. 5,294,869 and 5,151,629; rare earth metal, actinide or transition metal organic complex as disclosed in U.S. Pat. No. 6,524,727, all being incorporated herein by reference.

The active light-emission layer 60 region can also include any one or a mixture of two or more of fluorescent and phosphorescent materials including small molecules and polymers. For example, the active light-emission layer 60 may be comprised of those materials disclosed in United States Patent publication 20020180349. U.S. patent application Ser. Nos. 08/829,398; 09/489,144 and U.S. Pat. No. 6,057,048 also disclose materials which may be used for the light-emission layer and these references are incorporated herein in their entirety.

Electron transport layer 70 is preferably comprised of the fullerene compound C60 or Alq and has a thickness range from about 10 nm to about 100 nm. The ETL layer thickness may be selected to produce desired optical interference to generate multiple colors, colors of desired wavelength, and optimum optical power output.

N-doped electron injection layer (EIL) 80 is preferably comprised of a LiF doped electron transport material (ETM) and has a thickness range from about 1 nm to about 50 nm. Particularly, the molecules of the electron transport material and the dopant may be selected on the basis that the energy of the highest occupied molecular orbital (HOMO) of the donor is selected to match the lowest unoccupied molecular orbital (LUMO) of the fullerene. The energy difference between the HOMO and LUMO is preferably less than 0.5 eV.

The electron transport molecule is preferably tris (8-hydroxyquinolinato) (Alq3) or a fullerene such as C60, C70 or mixtures of C60 and C70. The alkali fluoride dopant may be LiF, MgF₂, CaF₂, SrF₂ and BaF₂, but is preferably LiF.

The preferred doping method is co-evaporation or LiF evaporation on top of the ETL to introduce a shallow n-doped region or referred to as delta-doping in the following discussion.

Cathode layer 90 is preferably aluminum (Al) which has a thickness of about 100 nm which has shown good behavior but other thicknesses may certainly be used. In addition, cathode 90 may be made of one or more layers of other well known conductive metals and/or alloys. For example, cathode 90 may be produced from one or more layers of highly conductive metals and alloys such as ITO, Al, Cr, Cu, Ag, Au, Ni, Fe, Ni, W, Mo, Co, Mg:Ag, Li:Al. An optional cathode capping layer 100 made of a dielectric, such as Si oxides and nitrides, may be deposited on the cathode by sputtering or any of the other coating techniques known to those skilled in the art.

The present invention provides a p-i-n structured light-emitting device which uses fullerene p-doped hole injection layer (HIL) and LiF n-doped electron injection layer (EIL). As discussed in Example 2 the fullerene p-doped HIL has much improved thermal stability. To further demonstrate the advantage of a fullerene p-doped p-i-n OLED over undoped i-n OLED, various fullerene concentrations and thicknessess were varied to optimized the device performance.

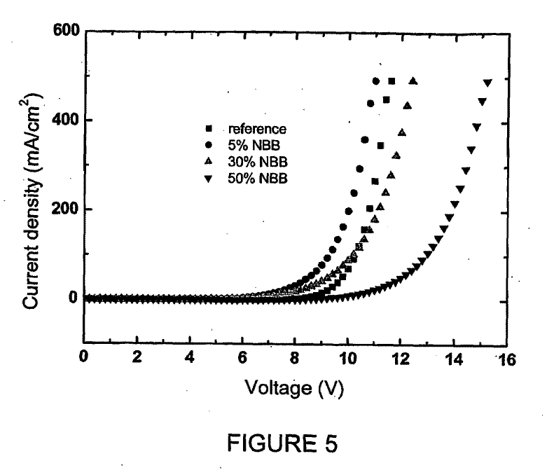

FIG. 5 shows plots of current versus voltage of P-I-N OLEDs constructed according to the present invention. Here a 10 nm thick p-doped hole injection layer consists of NPB doped with 0% (reference device), 3 wt %, 30 wt %, and 50% fullerene nano-bucky-ball (NBB) respectively. The HTL is 50 nm thick NPB. The emission “I” layer is 40 nm thick Alq, which also functions as ETL. The n-type 1.5 nm LiF delta-doping electron injection layer is introduced at the interface between ETL Alq and Al cathode.

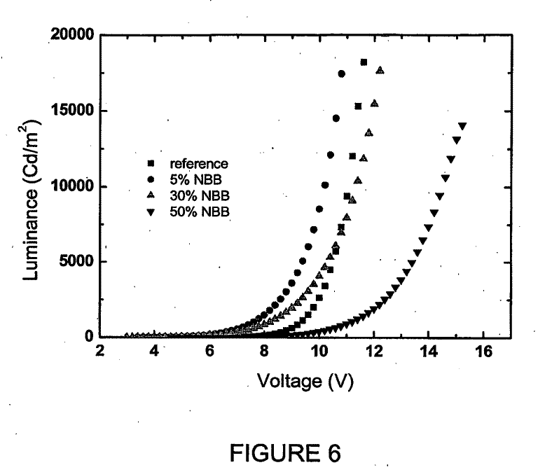

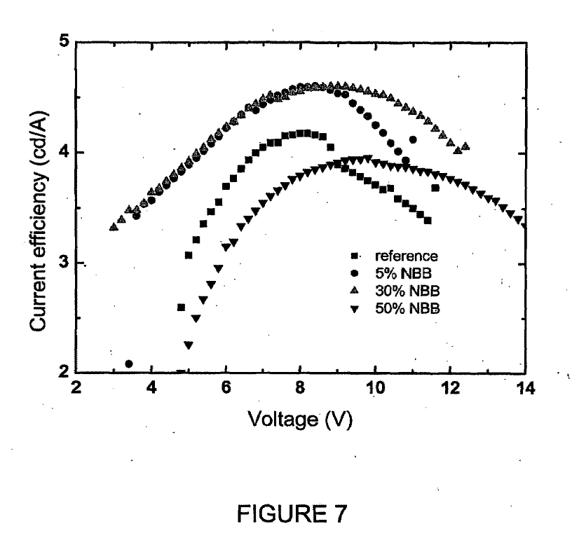

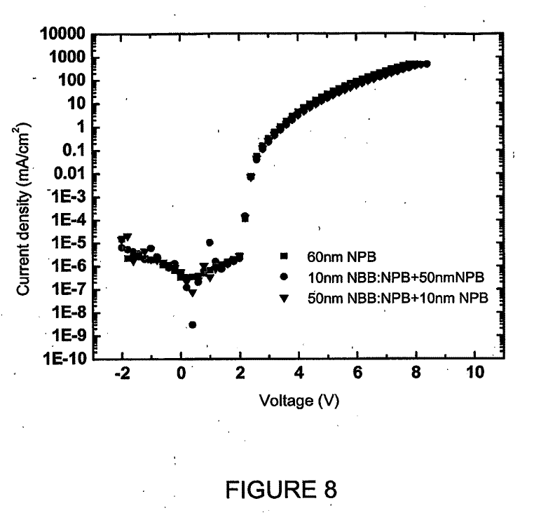

The luminance-voltage characteristic of the P-I-N OLED is shown in FIG. 6. FIG. 7 shows plots of current efficiency as a function of operating voltage of the P-I-N OLEDs. FIG. 8 shows plots of current versus voltage of the P-I-N OLEDs. Here the C60 doping concentration is 5 wt. % for all cases.

The test results clearly demonstrate the electrical advantages of P-I-N OLED with 5 wt. % doping level. The advantages include lower driving voltage at a given current (FIG. 5), lower driving voltage at a given luminance (FIG. 6), and higher current efficiency (FIG. 8).

In order to further test the applicability of thicker p-doped HIL, we have constructed the same P-I-N OLED where p-doped thickness varies from 10 nm to 50 nm where the HTL thickness varies from 50 nm to 10 nm, respectively to maintain the same 60 nm sum thickness of HIL and HTL.

FIG. 8 shows plots of current versus voltage of the P-I-N OLEDs constructed according to the present design. Here the C60 doping concentration is 5 wt. % for all cases.

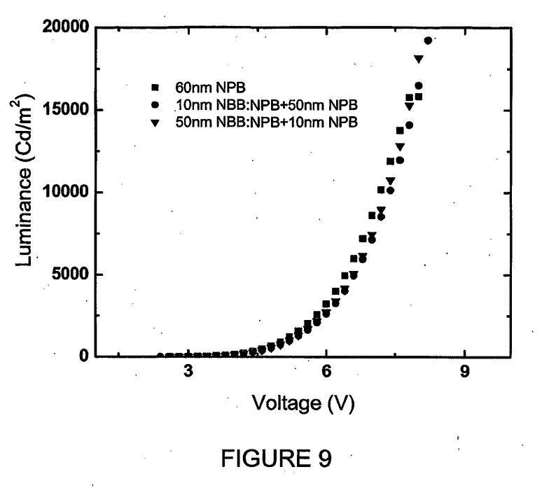

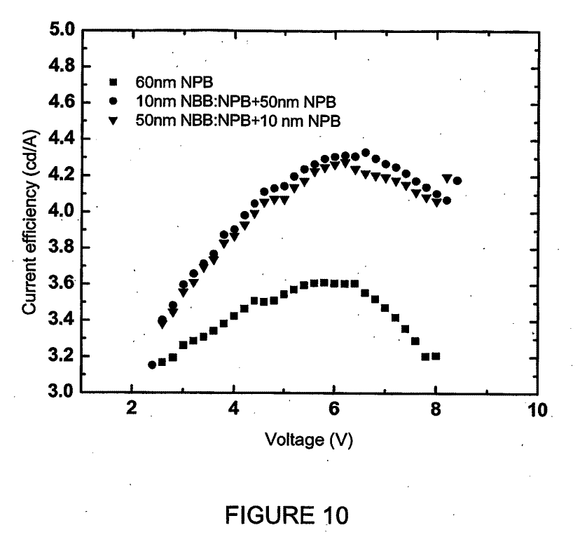

FIG. 9 shows luminance versus voltage characteristics of the same P-I-N OLEDs. FIG. 10 shows the current efficiency versus voltage characteristics of the same P-I-N OLEDs.

FIG. 10 shows plots of current efficiency versus voltage of P-I-N OLEDs in which the thickness of 5 wt. % C60-doped NPB is varied from 0 nm, 10 nm, to 50 nm. The emission “I” layer includes a 40 nm thick Alq. The n-doped electron injection layer is the Alq delta doped with 1.5 nm thick LiF.

FIG. 8-10 clearly show that the fullerene p-doped hole injection layer (HIL) thickness can be selected over a wide thickness range.

As used herein, the terms “comprises”, “comprising”, “including” and “includes” are to be construed as being inclusive and open ended, and not exclusive. Specifically, when used in this specification including claims, the terms “comprises”, “comprising”, “including” and “includes” and variations thereof mean the specified features, steps or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

1. A molecular film comprising an electron transport material including molecules which transport electrons and an alkali fluoride as a dopant, wherein charge transfer between the molecules which transport electrons and the dopant produces n-type doping to the molecules which transport electrons.

2. The molecular film of claim 1 wherein said electron transport molecule is tris (8-hydroxyquinolinato) aluminum (Alq3).

3. The molecular film of claim 1 wherein said electron transport molecule is a fullerene selected from the group consisting of C60, C70 and mixtures of C60 and C70.

4. The molecular film of claim 1 wherein said alkali fluoride is selected from the group consisting of LiF, MgF₂, CaF₂, SrF₂ and BaF₂.

5. The molecular film of claim 1 wherein said alkali fluoride is LiF.

6. The molecular film of claim 1 applied as an electron transport layer on a hole transport layer to form a p-n junction.

7. The molecular film of claim 1 applied as an interlayer between a metal electrode and a surface of a source junction in an n-type channel, and/or applied as an interlayer between a metal electrode and a drain junction of said n-type channel of a field-effect transistor.

8. A molecular film comprising a hole transport material comprising molecules which transport holes and a fullerene as a dopant, wherein charge transfer between the molecules which transport holes and the dopant produce p-type doping to the molecules which transport holes.

9. The molecular film of claim 8 wherein said molecules which transport holes are selected from the group consisting of NPB (N,N′-bis(I-naphthyl)-N,N′-diphenyl-1,1′-biphenyl-4,4′-diamine) and TPD (N,N′-diphenyl-N,N′-bis(3-methylphenyl)-1,1′-biphenyl-4,4′-diamine).

10. The molecular film of claim 8 wherein said fullerene is selected from the group consisting of C60, C70 and mixture of C60 and C70.

11. The molecular film of claim 8 for use as a primer coat on a surface for improved adhesion and thermal stability.

12. The molecular film of claim 8 applied as a hole transport layer on an electron transport layer to form a p-n junction.

13. The molecular film of claim 8 applied as an interlayer between a metal electrode and a surface of a source junction in an p-type channel, and/or applied as an interlayer between a metal electrode and a drain junction of said p-type channel of a field-effect transistor.

14. A light-emitting device, comprising:
a) a substrate;
b) a first electrically conductive layer defining an anode electrode layer on the substrate;
c) a p-type doped hole injection layer on the anode electrode layer:
d) a hole transport layer on the p-type doped hole injection layer;
e) a layer of electroluminescent material located on said hole transport layer;
f) an electron transport layer on the layer of electroluminescent material;
g) an n-type doped electron injection layer located on said electron transport layer; and
h) a second electrically conductive layer defining a cathode electrode layer on said n-type doped electron injection layer, wherein either said first electrically conductive layer and the substrate is at least partially transparent or the a second electrically conductive layer is transparent to light produced in said light emissive material.

15. The light-emitting device of claim 14 wherein said p-type hole injection layer is NPB (N,N′-bis(I-naphthyl)-N,N′-diphenyl-1,1′-biphenyl-4,4′-diamine) doped with a fullerene selected from the group consisting of C60 and C70 and mixtures of C60 and C70.

16. The light-emitting device of claim 14 wherein said p-type hole injection layer is TPD (N,N′-diphenyl-N,N′-bis(3-methylphenyl)-1,1′-biphenyl-4,4′-diamine) doped with a fullerene as dopant, the fullerene being selected from the group consisting of C60 and C70 and mixtures of C60 and C70.

17. The light-emitting device of claim 15, wherein said dopant fullerene is C60 present with a weight percentage from about 1 wt. % to about 50 wt. %, and wherein p-type hole injection layer has a thickness in a range from about 1 nm to about 300 nm

18. The light-emitting device of claim 14 wherein said hole injection layer has a thickness in a range from about 5 nm to 50 nm.

19. The light-emitting device of claim 16 wherein said C60 is present in a concentration range from about 1 wt. % to about 30 wt. %.

20. The light-emitting device according to claim 14 wherein said second electrically conductive layer defining a cathode electrode layer is selected from the group consisting of Al, Cr, Cu, Ag, Au, Ni, Fe, Ni, W, Mo, Co, metal alloys and metal mixtures.

21. The light-emitting device of claim 20 wherein said alloy is a Mg:Ag or Li:Al alloy.

22. The light-emitting device of claim 14 wherein said n-type electron injection layer includes an electron transport material including molecules which transport electrons and an alkali fluoride as a dopant, wherein charge transfer between the molecules which transport electrons and the dopant produces n-type doping in the molecules which transport electrons.

23. The light-emitting device of claim 14 wherein said molecules which transport electrons are selected so that an energy of the highest occupied molecular orbital (HOMO) of the dopant is selected to match a lowest unoccupied molecular orbital (LUMO) of the molecules which transport electrons.

24. The light-emitting device of claim 14 wherein said molecules which transport electrons is selected from the group consisting of tris (8-hydroxyquinolinato) (Alq3), fullerene selected from the group consisting of C60 and C70 and mixtures of C60 and C70.

25. The light-emitting device of claim 22 wherein said alkali fluoride is selected from the group consisting of LiF, MgF₂, CaF₂, SrF₂ and BaF₂.

26. The light-emitting device of claim 22 wherein said alkali fluoride compound is lithium fluoride (LiF).

27. The light-emitting device of claim 14 wherein said n-type electron injection layer has a thickness in a range from about 1 nm to about 50 nm.

28. The light-emitting device of claim 14 wherein said electroluminescent material is selected from the group consisting of tris-(8-hydroxyquinoline) aluminum (Alq3), electroluminescent organic compounds and electroluminescent conjugated polymers, and rare earth metal, actinide or transition metal organic complexes.

29. The light-emitting device of claim 16 wherein said dopant fullerene is C60 present with a weight percentage from about 1 wt. % to about 50 wt. %, and wherein p-type hole injection layer has a thickness in a range from about 1 nm to about 300 nm.
